(19) United States
(12) Patent Application Publication
(10) Pub. No.: US 2026/0322352 A1
(43) Pub. Date: Oct. 15, 2026

(54) LAMB WAVE RESONATOR HAVING THROUGH HOLE

(71) Applicant: NANJING UNIVERSITY, Jiangsu (CN)

(72) Inventors: Siyuan YU, Jiangsu (CN); Shumao WU, Jiangsu (CN); Zhenhui QIN, Jiangsu (CN); Chenbei HAO, Jiangsu (CN); Yanfeng CHEN, Jiangsu (CN)

(73) Assignee: NANJING UNIVERSITY, Jiangsu (CN)

(21) Appl. No.: 19/483,980

(22) PCT Filed: Apr. 26, 2024
(86) PCT No.: PCT/CN2024/089498

§ 371 Date: Nov. 13, 2025

(30) Foreign Application Priority Data
May 19, 2023 (CN) 202310570704.1
Jan. 16, 2024 (CN) 202410062601.9

(51) Int. Cl. H03H 9/13; H03H 9/02; H03H 9/17

(52) U.S. Cl. CPC H03H 9/131; H03H 9/0211; H03H 9/02228; H03H 9/176

(57) ABSTRACT

Disclosed in the present invention is a Lamb wave resonator having a through hole, comprising a piezoelectric layer thin film. The Lamb wave resonator further comprises one or multiple through holes arranged within an interdigital electrode region of the piezoelectric layer thin film.

The present application claims the priority benefit of the prior application to:
the Chinese Patent Application No. 2024100626019, titled “Lamb Wave Resonator Having Through Hole” and filed with Chain National Intellectual Property Administration on Jan. 16, 2024 by the Applicant; and
the Chinese Patent Application No. 2023105707041, titled “Lamb Wave Resonator Having Through Hole” and filed with Chain National Intellectual Property Administration on May 19, 2023 by the Applicant; and
the full texts of the foregoing prior applications are incorporated herein by reference.

### TECHNICAL FIELD

The present invention relates to the technical field of resonators, and in particular to a Lamb wave resonator having a through hole.

### BACKGROUND

Microwave acoustic filters have long been widely used in the field of mobile communications. With the rapid development of new-generation communication technologies, the demand for more compact filters operating at higher frequency bands and with larger bandwidths is growing significantly.

At present, mainstream commercial microwave acoustic filters primarily adopt two technological approaches. One approach is the surface acoustic wave (SAW) filter based on piezoelectric single crystals such as lithium niobate (LiNbO₃) and lithium tantalate (LiTaO₃). The operating frequency of these devices is limited by the transducer electrode linewidth, typically below 3.5 GHz. Further scaling to higher frequencies would result in a sharp increase in cost and technical difficulty. The other approach is the bulk acoustic wave (BAW) filter based on piezoelectric thin films, such as aluminum nitride (AlN). These devices have the advantage of enabling filters operating above 3.5 GHz relatively easily. However, limited by the low electromechanical coupling coefficient of AIN thin films, these filters usually exhibit limited bandwidth. Facing the complex application scenarios for next-generation and future communication technologies, conventional SAW and BAW filters are encountering numerous challenges.

In addition to the longitudinal BAW mode, acoustic modes in thin films also include Lamb wave modes and shear horizontal (SH) modes. Lamb wave modes are further categorized into symmetric(S) modes and antisymmetric (A) modes. Acoustic resonators operating based on these modes (such as A₁, S₂, A₃, and S₄ resonators based on LiNbO₃ single-crystal thin films) are particularly advantageous for achieving high-frequency and wide-bandwidth acoustic filters: 1) acoustic resonance at frequencies in GHz range or even higher can be achieved with interdigital transducers having linewidth on the order of micrometers; and 2) these resonators can have very high electromechanical coupling coefficients, which is beneficial for achieving ultra-wideband filters.

Although Lamb wave resonators can allow the implementation of high-frequency and ultra-wideband filters, these resonators inherently generate numerous parasitic modes, and suppressing these modes remains a significant challenge in resonator design. Existing techniques for suppressing parasitic modes either require additional device fabrication steps or impose extremely stringent requirements on electrode design, making it difficult to completely suppress or eliminate the parasitic modes.

### SUMMARY

To address the aforementioned problems, the present invention aims to provide a Lamb wave resonator having a through hole. By introducing the through hole within an interdigital electrode region of the piezoelectric layer thin film, parasitic modes can be conveniently and efficiently suppressed or even completely eliminated.

In order to achieve the above objectives, the present invention, in one aspect, provides a Lamb wave resonator having a through hole, which includes a piezoelectric layer thin film. The Lamb wave resonator further includes one or more through holes arranged in an interdigital electrode region of the piezoelectric layer thin film.

In the context of the present invention, the term “interdigital electrode region” refers to a maximum area enclosed by fingers of the interdigital electrode and mutually parallel first and second busbar electrodes.

In one embodiment of the present invention, the through holes are formed in the piezoelectric layer thin film in an ordered manner or a disordered manner.

A shape of the through hole is not particularly limited and may be regular or irregular, for example, it may be one or more of circular, elliptical, square, rectangular, rhombic, trapezoidal, arcuate, annular, spiral, or any other regular or irregular polygons.

In one embodiment of the present invention, a size of the through hole is 0.20 μm-100 um, more preferably 0.2 μm-1.5 82 m, and further preferably 0.50 82 m-1.25 μm. For example, 0.50 μm, 0.60 μm, 0.70 82 m, 0.75 82 m, 0.80 μm, 0.90 μm, 1.00 82 m, 1.10 μm, 1.20 μm, 1.25 μm, or any value within any range or range between any two values mentioned above.

In the context of the present invention, the size of the through hole refers to a maximum distance between two points in a cross section of the through hole. For example, when the cross section of the through hole is circular, the size of the through hole is a diameter of the circle. When the cross section of the through hole is rectangular, the size of the through hole is a diagonal length of the rectangle. When the cross section of the through hole is elliptical, the size of the through hole is a length of the major axis of the ellipse.

In one embodiment of the present invention, a vertical distance between two adjacent through holes is 8-12 μm, and a horizontal distance is 8-22 μm. po In one embodiment of the present invention, the through holes are arranged in the interdigital electrode region in a periodic or non-periodic manner. “Periodic arrangement” means that distances between two adjacent through holes arranged in a vertical direction and in a horizontal direction are equal. Periodic arrangement means that a distance between two adjacent through holes arranged in a vertical direction is equal, and a distance between two adjacent through holes arranged in a horizontal direction is also equal. Distances between two adjacent through holes arranged in the vertical direction and two adjacent through holes arranged in the horizontal direction may be equal or unequal.

In one embodiment of the present invention, the through holes are arranged in the interdigital electrode region in a dense manner or a sparse manner. Specifically, “dense arrangement” means that a distance between two adjacent through holes arranged in the vertical direction is 0.5 μm-10 μm, preferably 2 μm-10 μm, and more preferably 5 μm-8 μm. “Sparse arrangement” means that a distance between two adjacent through holes arranged in the vertical direction is more than 10.0 μm.

A number of through holes is not particularly limited in the present invention, provided that it is more than one.

In one embodiment of the present invention, the number of through holes may be 1-4,000; preferably 1-2,000, more preferably 1-1,000, and further preferably 1-200, for example 1-100.

In one embodiment of the present invention, the Lamb wave resonator further includes an optional temperature compensation layer.

In one embodiment of the present invention, the through hole penetrates the piezoelectric layer thin film in a thickness direction and extends downward, either penetrating or not penetrating the temperature compensation layer.

In one embodiment of the present invention, the temperature compensation layer is located above or below the piezoelectric layer thin film, or between the same.

In one embodiment of the present invention, the Lamb wave resonator further includes an optional fixed substrate layer.

In one embodiment of the present invention, the through hole penetrates the piezoelectric layer thin film in a thickness direction and extends downward, either penetrating or not penetrating the fixed substrate layer.

In one embodiment of the present invention, the fixed substrate layer is located below the piezoelectric layer thin film.

Preferably, the fixed substrate layer includes at least one layer, more preferably at least two layers.

Preferably, the fixed substrate layers may be made of the same or different materials, and are independently selected from at least one of Pt, Al₂O₃, W, Mo, BCB, Si, SiC, SiO₂, or diamond.

In the present invention, no particular limitation is imposed on a thickness of the temperature compensation layer, for example, the thickness may be 0 μm-100 μm, where a thickness of 0 indicates the absence of a temperature compensation layer.

In the present invention, no particular limitation is imposed on a material of the temperature compensation layer, for example, it may include one or more of SiO₂, GeO₂ and Si₂OF₆.

In one embodiment of the present invention, a material of the piezoelectric layer thin film is selected from one or more of LiNbO₃, LiTaO₃, AlN, AlScN, ZnO, and PbZrTiO₃; preferably LiNbO₃, LiTaO₃, AlN and AlScN; and more preferably LiNbO₃ and LiTaO₃.

In a preferred embodiment of the present invention, the piezoelectric layer thin film is a LiNbO₃ single-crystal thin film, where the LiNbO₃ single-crystal thin film includes a suspended LiNbO₃ single-crystal thin film portion and an unsuspended LiNbO₃ single-crystal thin film portion; and interdigital electrodes are disposed on the suspended LiNbO₃ single-crystal thin film portion; and the through holes are arranged on a surface of the suspended LiNbO₃ single-crystal thin film portion and located between the interdigital electrodes.

Preferably, a cut orientation of the piezoelectric layer thin film includes all possible cut orientations of the piezoelectric layer thin film, for example Z-cut, Y-cut, or 128° Y-cut.

No particular limitation is imposed on a thickness of the piezoelectric layer thin film, which may be 50-5,000 nm, preferably 300-900 nm.

In one embodiment of the present invention, the interdigital electrode is configured as a periodic structure or a weighted electrode structure.

In one embodiment of the present invention, a period direction of the interdigital electrode may be in any direction within a portion of the suspended LiNbO₃ single-crystal thin film portion.

The interdigital electrode includes N sets of first fingers and N-1 sets of second fingers spaced apart, where N is an integer greater than or equal to 2. Preferably, the through holes are arranged in a middle of the interdigital electrode, and located at any position to the left or right between the N sets of first fingers and the N sets of second fingers.

In one embodiment of the present invention, the interdigital electrode includes a first busbar electrode and a second busbar electrode arranged parallel to each other; the first busbar electrode is connected to an input terminal, and the second busbar electrode is grounded; a plurality of sets of first fingers are disposed on the first busbar electrode, a plurality of sets of second fingers are disposed on the second busbar electrode, and the plurality of sets of first fingers and the plurality of sets of second fingers are arranged sequentially at intervals.

In one embodiment of the present invention, the first busbar electrode is connected to the N sets of first fingers, and the second busbar electrode is connected to the N-1 sets of second fingers.

A width of the interdigital electrode may be 0.1 μm-20 μm, preferably 0.5 μm-10 μm; a distance may be 2 μm-100 μm; and a thickness may be 5 μm-1000 nm, and preferably 10 nm-600 nm.

A length of the overlapping portion of the first fingers and the second fingers defines an aperture of the interdigital electrode. The aperture of the interdigital electrode may be 5 μm-800 μm, preferably 20 μm-500 μm, and more preferably 70 μm-100 μm, for example, 70 μm, 75 μm, 80 μm, 85 μm, 90 μm, or any value within any range or range between any two values mentioned above.

In one embodiment of the present invention, materials of the interdigital electrodes, as well as the first and second busbar electrodes, may be any conductive material, for example, one or more selected from graphene, topological semimetals, Al, Au, Pt, Cr, W, Mo, Ni, Fe, or Ti.

In one embodiment of the present invention, the Lamb wave resonator further includes release windows disposed in the piezoelectric layer thin film. The release windows are distributed on a lower side of the first busbar electrode, and on an upper side of the second busbar electrode.

In the present invention, no particular limitation is imposed on a shape of the release window. For example, the release windows have a rectangular cross section and are hollow. Four release windows are distributed on the lower side of the first busbar electrode, and three release windows are distributed on the upper side of the second busbar electrode.

The present invention has the following beneficial effects:
1) Suppression of parasitic modes: During the operation of the resonator, a voltage is applied to the electrode structure. Due to the excellent piezoelectric properties of the piezoelectric film (e.g., LiNbO₃ single-crystal thin film), the electrical loading induces mechanical stress in the piezoelectric film beneath the electrodes, resulting in acoustic wave reflections at the electrode edges. The acoustic wave reflections at the electrode edges are a potential cause of higher-order lateral parasitic modes. In the present invention, sub-wavelength through holes are introduced between the interdigital electrodes on the surface of the piezoelectric layer thin film. Due to the air gap between the interdigital electrodes, a significant acoustic impedance mismatch exists between the air and the piezoelectric thin film, which suppresses the acoustic wave reflections generated at the electrode edges. As a result, higher-order lateral parasitic modes are conveniently, efficiently and completely suppressed, while the fundamental mode is almost unaffected.
2) Relaxation of design requirements and difficulties of resonators: For existing Lamb wave resonators, the dimensions must be strictly controlled to minimize parasitic modes. For the Lamb wave resonators in the prior art, parasitic modes are highly dependent on the electrode spacing and duty cycle. With very small electrode spacing, higher-order parasitic modes almost inevitably appear, while with very large spacing, parasitic modes can be partially suppressed. In the existing structure of the Lamb wave resonators, release windows are often located around a periphery of the interdigital electrodes. During the release process, whether by wet etching or dry etching, the substrate material must be etched from the outer release windows inward. Excessively large electrode spacing increases the device area, especially for resonators with a great number of electrode pairs, significantly increasing the back-etching (release) time and fabrication difficulty. Moreover, the release process is isotropic; etching from the outside inward also etches the substrate in the opposite direction, resulting in an excessively large suspended area, which adversely affects device layout. Excessive suspended area of the resonator affects mechanical stability and hinders the design of miniaturized acoustic filters. When the electrode width is reduced to below 1 μm, parasitic modes could be suppressed through smaller spacing or a suitable duty cycle, but this imposes stringent requirements on photolithography. To completely suppress the parasitic modes, the thickness of interdigital electrodes must fall within a very small range.

The through hole structure of the present invention is applicable to any electrode configuration, regardless of small or large electrode spacing, the through holes can effectively suppress parasitic modes without performing any additional fabrication steps, thereby relaxing the design parameter requirements of the resonator and avoiding the need for strict parameter limits. For various resonator design parameters (including different interdigital electrode apertures, different electrode duty cycles, and different LiNbO₃ thin film thicknesses), all resonators with through holes are more likely to achieve admittance responses free of parasitic modes. This design is highly universal and adaptable.
3) Through holes can serve as release windows to reduce ineffective suspended area of the piezoelectric thin film, and improve stability and compactness of the device: The through holes can serve as release windows, reducing or eliminating the need for peripheral release windows. During the release process of resonator fabrication, etching gas (or liquid) can simultaneously etch the substrate material both from inside outward and outside inward through a through hole structure, significantly shortening the etching time. This reduces time and cost of device fabrication, while minimizing the ineffective suspended area of the piezoelectric thin film. The reduction of the ineffective suspended area of the piezoelectric thin film is of great value. It is beneficial to the mechanical stability and compactness of the resonator, and facilitates faster heat conduction from the resonator to the substrate, thereby improving the temperature stability and power tolerance of the resonator.

### BRIEF DESCRIPTION OF THE DRAWINGS

FIG. 1(a) is a top view of the Lamb wave resonator in Example 1; and FIG. 1(b) is a side view of the Lamb wave resonator in Example 1.

FIG. 2 illustrates admittance spectra of a Lamb wave resonator with different aperture diameters in Example 1.

FIG. 3 illustrates admittance spectra of a Lamb wave resonator with different electrode structures in Example 2.

FIG. 4 illustrates admittance spectra of a Lamb wave resonator with different thicknesses of piezoelectric thin film in Example 3.

FIG. 5 illustrates admittance spectra of a Lamb wave resonator with different through hole arrangements in Example 4.

FIG. 6 illustrates admittance spectra of a Lamb wave resonator with a piezoelectric material changed to a LiTaO₃ thin film in Example 5.

FIG. 7 illustrates admittance spectra of a Lamb wave resonator with an electrode material changed to A1 in Example 7.

FIG. 8 illustrates admittance spectra of a LiNbO₃-based Lamb wave resonator with through holes of circular, square, elliptical, triangular, and rectangular shapes, in Example 8.

### DETAILED DESCRIPTIONS OF THE EMBODIMENTS

The technical solution of the present invention will be further described in detail below with reference to the specific embodiments. It should be understood that the following examples are only used for exemplary illustration and explanation of the present invention, and should not be construed as limiting the scope of protection for the present invention. The technology completed based on the content mentioned above should fall within the scope of protection of the present invention.

Unless otherwise defined, all technical and scientific terms mentioned herein have the same meaning as commonly understood by those skilled in the technical field of the present invention. Terms mentioned in the description of the present invention are used only for the purpose of describing specific embodiments, and are not intended to limit the present invention.

### Example 1

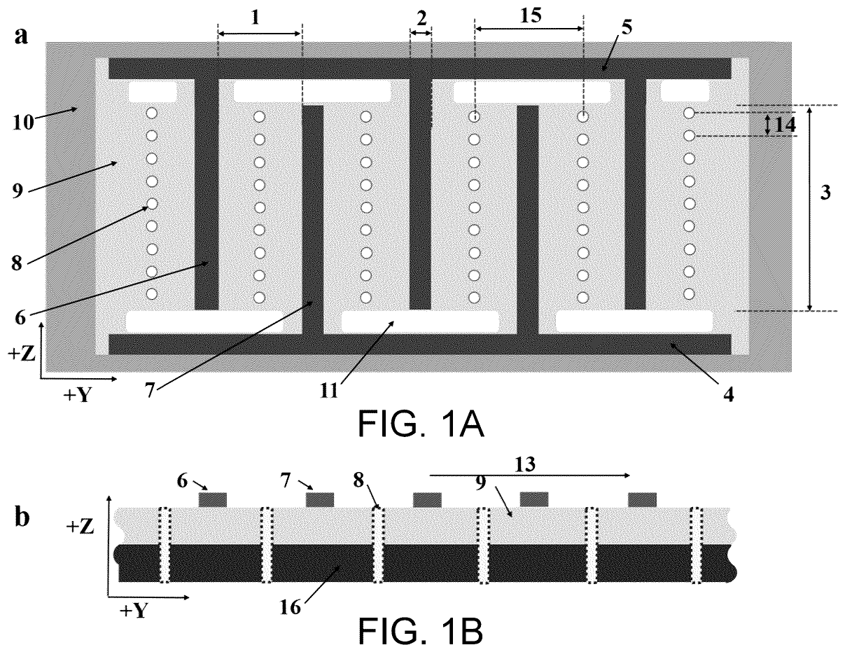

As shown in FIG. 1, a LiNbO₃-based Lamb wave resonator includes a LiNbO₃ single-crystal thin film, where the LiNbO₃ single-crystal thin film includes a suspended LiNbO₃ single-crystal thin film portion 9 and an unsuspended LiNbO₃ single-crystal thin film portion 10, Z-cut with a thickness of 300 nm. An interdigital electrode, a through hole 8, and a release window 11 are disposed on the suspended LiNbO₃ single-crystal thin film portion 9.

An interdigital electrode layer includes a first busbar electrode 5 and a second busbar electrode 4, which are arranged parallel to each other, with a width of 5 μm. The first busbar electrode 5 is connected to an input terminal, and the second busbar electrode 4 is grounded. N sets (N equals 3) of first fingers 6 are disposed on the first busbar electrode 5, and N-1 sets of second fingers 7 are disposed on the second busbar electrode 4. The N sets of first fingers 6 and the N-1 sets of second fingers 7 are alternately arranged. A distance, denoted by 1, between one first finger 6 and an adjacent second finger 7 is 8 μm, and a width, denoted by 2, of each first finger or second finger is 2 μm.

A length of the overlapping portion of the first fingers 6 and the second fingers 7 defines an aperture 3 of the interdigital electrode. The aperture 3 of the interdigital electrode is 90 μm. The interdigital electrode is made of gold (Au) with a thickness of 50 nm (that is, a thickness of the first finger 6 and the second finger 7 between the first busbar electrode 5 and the second busbar electrode 4, including the thickness of the first busbar electrode 5 and the second busbar electrode 4). In FIG. 1, reference numeral 13 denotes a period direction of the interdigital electrode.

The through hole 8 is disposed in a region between a surface of the unsuspended LiNbO₃ single-crystal thin film portion 10 and the interdigital electrode. The through hole is circular with a diameter ranging from 0 μm to 1.25 μm. A vertical distance, denoted by 14, between two adjacent through holes is 10 μm, and each vertical column contains 9 through holes. A horizontal distance, denoted by 15, between two adjacent through holes is 20 μm, and each horizontal row contains 6 through holes. A total of 54 through holes are periodically arranged on the surface of the unsuspended LiNbO₃ single-crystal thin film portion 10.

As shown in FIG. 1(a), the release window 11 has a rectangular cross section and is hollow. Four release windows are distributed on a lower side of the first busbar electrode 5, and three release windows are distributed on an upper side of the second busbar electrode 4. The SiO₂ 16 has a thickness of 0 μm.

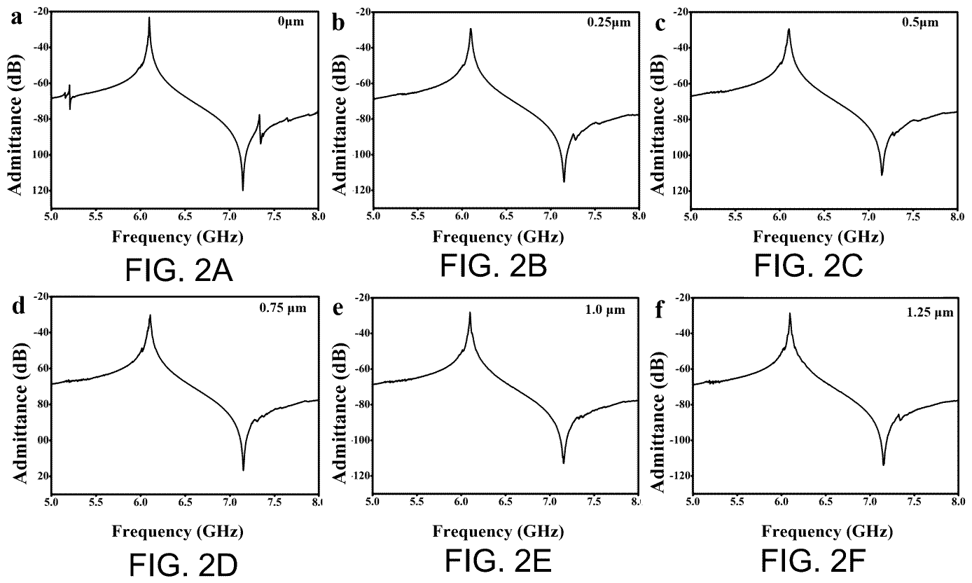

To verify the effect of through holes on the suppression of parasitic modes in the resonator, admittance spectra of the resonator with and without through holes are calculated using a three-dimensional full-model finite element simulation, as shown in FIG. 2.

FIGS. 2a-2f illustrate the admittance spectra of the LiNbO₃-based Lamb wave resonator with through hole diameters of 0 μm (that is, without through hole), 0.25 μm, 0.50 μm, 0.75 μm, 1.00 μm, and 1.25 μm, respectively.

Without the through hole (FIG. 2a), the admittance spectrum of the LiNbO3-based Lamb wave resonator exhibits a distinct parasitic mode. When the through hole has a relatively small diameter, such as 0.25 μm (FIG. 2b), the parasitic mode is suppressed to some extent, but it still exists. As the through hole diameter increases to 0.50 μm (FIG. 2 c), the parasitic mode is almost completely suppressed. When the diameter continues to increase to 0.75 μm (FIG. 2 d) and 1.00 um (FIG. 2(e)), the parasitic mode remains suppressed. When the diameter further increases to 1.25 μm (FIG. 2f), the parasitic mode reappears, but it is still significantly suppressed compared to the case without the through hole. In the above cases, the admittance and the resonance frequency of the fundamental mode of the LiNbO₃-based Lamb wave resonator remain almost unchanged.

### Example 2

The through hole provided in the present invention exhibits excellent applicability for various interdigital electrode designs.

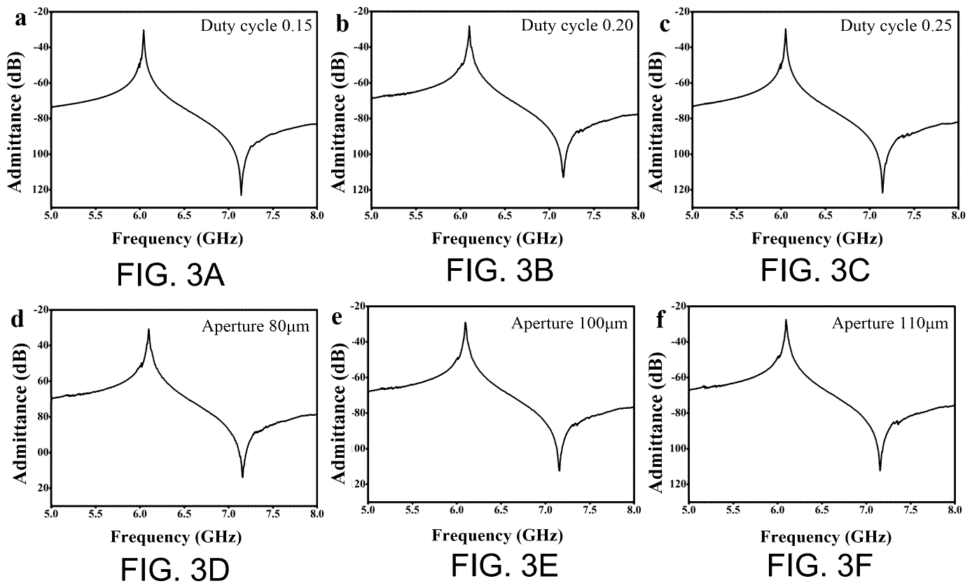

To verify this, admittance spectra of LiNbO₃-based Lamb wave resonators with various interdigital electrode design parameters under identical through hole configurations (with a hole diameter of 1.0 μm), as shown in FIG. 3. The Lamb wave resonators used in this embodiment are the same as those in Example 1, except that the duty cycle and the aperture of the interdigital electrodes were varied.

FIGS. 3a-3c illustrate the admittance spectra of the resonators with different duty cycle values (0.15, 0.20, and 0.25), respectively. FIGS. 3d-3f illustrate the admittance spectra of the resonators with different interdigital electrode apertures (80 μm, 100 μm, and 110 μm), respectively. It can be seen that, after introducing identical through holes into all Lamb wave resonators, the parasitic modes on a right side of the anti-resonance peak were effectively suppressed.

### Example 3

The through hole provided in the present invention is also applicable to LiNbO₃ single-crystal thin films with different thicknesses.

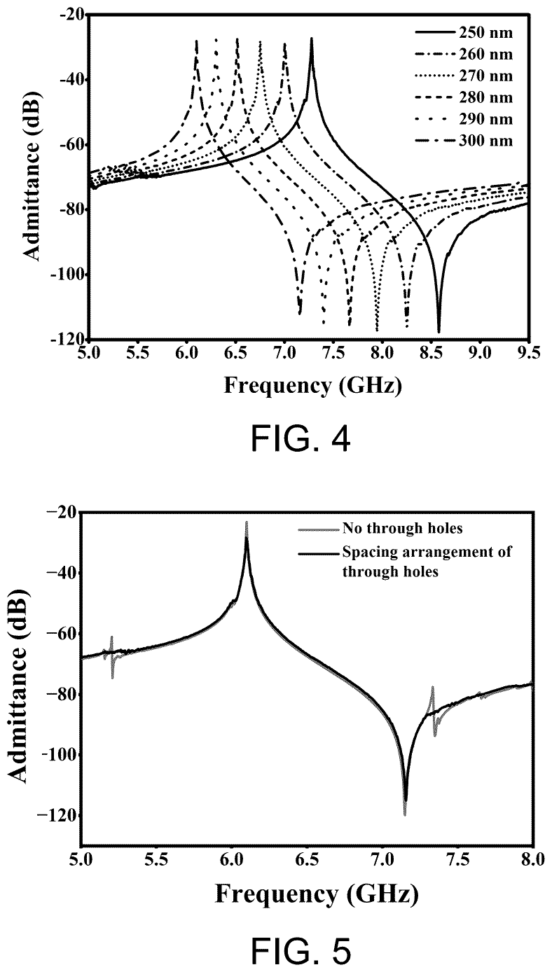

To verify this, taking the resonator with a through hole diameter of 1.0 μm in Example 1 as an example, an admittance spectrum of the resonator was calculated under varying thickness in the LiNbO₃ single-crystal thin film. Results were shown in FIG. 4.

It can be seen that, as a thickness of the LiNbO₃ single-crystal thin film was reduced from 300 nm to 250 nm, no parasitic modes appeared in the admittance spectra of the resonator. Meanwhile, a resonance frequency of the resonator increased almost linearly.

### Example 4

This example is substantially the same as Example 1, except that:

The through hole has a diameter of 1.0 μm. In a first column, a distance between two adjacent through holes is 10 μm, and a total of nine through holes are arranged in a vertical direction. In a second column, a distance between two adjacent through holes is 10 μm, and a total of eight through holes are arranged in a vertical direction. Different numbers of through holes are periodically arranged in a horizontal direction, with a horizontal distance of 20 μm between two adjacent through holes. A total of 51 through holes are arranged. As shown in FIG. 5, when the through holes in the resonator are arranged in a distance configuration, the parasitic modes on the right side of the anti-resonance peak are also effectively suppressed.

### Example 5

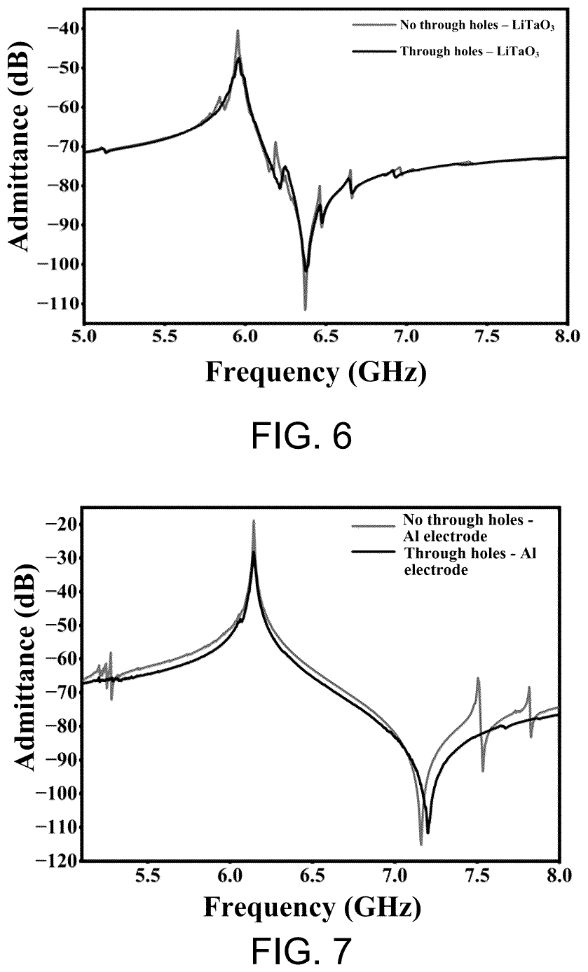

Based on Example 1, the piezoelectric layer was replaced with a LiTaO3 thin film having a thickness of 500 nm. The interdigital electrode parameters are the same as those in Example 1. The through hole has a diameter of 0.75 μm and a vertical spacing of 5 μm, 18 through holes are arranged per vertical column, and a horizontal spacing is 20 μm with 6 through holes per horizontal row. A total of 108 through holes are arranged. As shown in FIG. 6, when the piezoelectric layer is a LiTaO3 film, the through hole structure has a certain suppression effect on the parasitic modes of the resonator.

### Example 6

Taking the resonator with a through hole diameter of 1.0 μm in Example 1 as an example, a fixed substrate is arranged below the LiNbO3 single-crystal thin film. From top to bottom, the fixed substrate consists of layers of SiO₂, tungsten (W), SiO₂, tungsten (W), and silicon (Si), with thicknesses of 300 nm, 500 nm, 400 nm, 300 nm and 525 μm, respectively.

### Example 7

Other parameters are the same as those of the resonator with a through hole diameter of 1.0 μm in Example 1, except as follows.

The interdigital electrode material is changed to aluminum (Al) with a thickness of 100 nm. 20 sets of first fingers 6 are disposed on the first busbar electrode 5, and 19 sets of second fingers 7 are disposed on the second busbar electrode 4. The N sets of first fingers 6 and the N-1sets of second fingers 7 are alternately arranged. A distance, denoted by 1, between one first finger 6 and an adjacent second finger 7 is 15 μm, and a width, denoted by 2, of each first finger or second finger is 5 μm. The through hole 8 is disposed between a surface of the suspended LiNbO₃ single-crystal thin film portion 10 and the interdigital electrode. The through hole is circular with a diameter of 1 μm. A vertical distance between two adjacent through holes is 10 μm, and each vertical column contains 9 through holes. A horizontal distance between two adjacent through holes is 40 μm, and each horizontal row contains 40 through holes. A total of 360 through holes are arranged. FIG. 7 illustrates the admittance spectra of the resonator with and without through holes. It can be seen that even when the electrode material is changed to Al, the through hole structure effectively suppresses the parasitic modes of the resonator.

### Example 8

The other parameters in this embodiment are the same as those in Example 1, except that:

A shape of the through hole is changed to circular, square, rectangular, equilateral triangular, or elliptical. A side length of the square is 1 μm; a side length of the equilateral triangle is 1 μm; length and width of the rectangle are 2 μm and 1 μm, respectively; and major axis and minor axis of the ellipse are 2 μm and 1 μm, respectively.

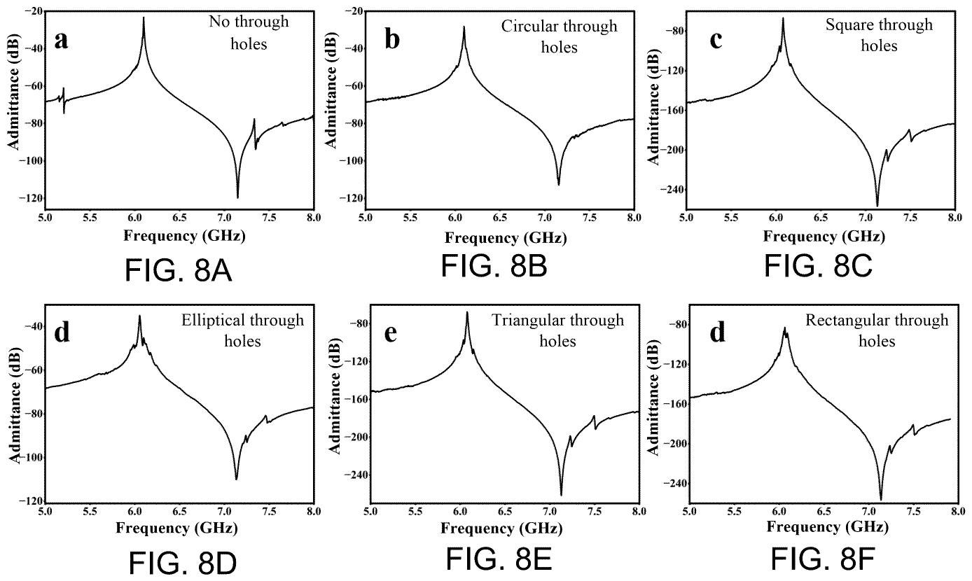

FIGS. 8a-8f illustrate the admittance spectra of the LiNbO₃-based Lamb wave resonators without through holes, and with through holes that are circular, square, elliptical, triangular, and rectangular, respectively. As shown in FIG. 8, through holes of different shapes all have a certain degree of suppression effect on parasitic modes, and when the through holes are circular, the suppression effect is the most pronounced.

Various technical features of the embodiments mentioned above may be arbitrarily combined. In order to simplify the description, not all possible combinations of the technical features in the above embodiments are described herein. However, as long as such combinations do not lead to contradictions, they should be considered to be within the scope of the specification.

1. A Lamb wave resonator having a through hole, comprising a piezoelectric layer thin film, wherein the Lamb wave resonator further comprises one or more through holes (8) arranged in an interdigital electrode region of the piezoelectric layer thin film.

2. The Lamb wave resonator according to claim 1, wherein the through holes (8) are a regular shape or an irregular shape, and are formed in the piezoelectric layer thin film in an ordered manner or a disordered manner;
preferably, a shape of the through holes (8) is one or more of circular, elliptical, square, rectangular, rhombic, trapezoidal, arcuate, annular, spiral, or any other regular or irregular polygons;
preferably, a size of the through holes (8) is 0.20 μm-100 μm, more preferably 0.2 μm-1.5 μm, and further preferably 0.50 μm-1.25 μm; and
for example, 0.50 μm, 0.60 μm, 0.70 μm, 0.75 μm, 0.80 μm, 0.90 μm, 1.00 μm, 1.10 μm, 1.20 μm, 1.25 μm, or any range between any two values mentioned above or any value within any range.

3. The Lamb wave resonator according to claim 1, wherein a number of the through holes (8) can be 1-4,000; preferably 1-2,000, more preferably 1-1,000, and further preferably 1-200, for example 1-100; and
preferably, a vertical distance between two adjacent through holes (8) is 8-12 μm, and a horizontal distance between the adjacent through holes (8) is 8-22 μm.

4. The Lamb wave resonator according to claim 1, wherein the through holes are arranged in a periodic manner or a non-periodic manner.

5. The Lamb wave resonator according to claim 1, wherein the through holes (8) are arranged within the interdigital electrode region in a dense manner or a sparse manner; and
for example, a distance between two adjacent through holes (8) arranged in a vertical direction is 0.5 μm-10 μm, preferably 2 μm-10 μm, and more preferably 5 μm-8 μm; or the distance between the two adjacent through holes arranged in the vertical direction is 10.5 μm or more.

6. The Lamb wave resonator according to claim 1, further comprising an optional temperature compensation layer (16), wherein the through holes penetrate through the piezoelectric layer thin film in a thickness direction and extend downward, either penetrating or not penetrating the temperature compensation layer (16);
preferably, the temperature compensation layer (16) is located above or below the piezoelectric layer thin film, or between the same;
preferably, a material of the temperature compensation layer (16) is selected from one or more of SiO₂, GeO₂ and Si₂OF₆;
preferably, the Lamb wave resonator further comprises an optional fixed substrate layer, wherein the through holes penetrate through the piezoelectric layer thin film in the thickness direction and extend downward, either penetrating or not penetrating the fixed substrate layer;
preferably, the fixed substrate layer is located below the piezoelectric layer thin film;
preferably, the fixed substrate layer has at least one layer, and more preferably at least two layers; and
preferably, a material of the fixed substrate layer is the same or different, and is independently from each other selected from at least one of Pt, Al₂O₃, W, Mo, BCB, Si, SiC, SiO₂, or diamond.

7. The Lamb wave resonator according to claim 1, wherein a material of the piezoelectric layer thin film is selected from one or more of LiNbO₃, LiTaO₃, AlN, AlScN, ZnO, PbZrTiO₃; preferably LiNbO₃, LiTaO₃, AlN, AlScN; and more preferably LiNbO₃ and LiTaO₃;
for example, the piezoelectric layer thin film is a LiNbO₃ single-crystal thin film, wherein the LiNbO₃ single-crystal thin film comprises a suspended LiNbO₃ single-crystal thin film portion (9) and an unsuspended LiNbO₃ single-crystal thin film portion (10); interdigital electrodes are disposed on the suspended LiNbO₃ single-crystal thin film portion (9); and the through holes (8) are arranged between the interdigital electrodes on a surface of the suspended LiNbO₃ single-crystal thin film portion (9);
preferably, a cut orientation of the piezoelectric layer thin film comprises all possible cut orientations of the thin film, for example Z-cut, Y-cut, or 128 ° Y-cut; and
preferably, a thickness of the piezoelectric layer thin film is 50-5,000 nm, and preferably 300-900 nm.

8. The Lamb wave resonator according to claim 1, wherein the interdigital electrode comprises a first busbar electrode (5) and a second busbar electrode (4) arranged parallel to each other; the first busbar electrode (5) is connected to an input terminal, and the second busbar electrode (4) is grounded; and a plurality of sets of first fingers (6) are disposed on the first busbar electrode (5), a plurality of sets of second fingers (7) are disposed on the second busbar electrode (4), and the plurality of sets of first fingers (6) and the plurality of sets of second fingers (4) are arranged sequentially at intervals;
preferably, the sets of first fingers (6) is N, and the sets of second fingers (7) is N1, wherein N is an integer greater than or equal to 2;
preferably, the first busbar electrode (5) is connected to the N sets of first fingers (6), and the second busbar electrode (4) is connected to the N1 sets of second fingers (7)[.]; and
preferably, the through holes (8) are arranged in a middle of the interdigital electrode, and located at any position to left or right between the N sets of first fingers (6) and the N sets of second fingers (7).

9. The Lamb wave resonator according to claim 8, wherein the interdigital electrode is configured as a periodic structure or a weighted electrode structure; and a period direction of the interdigital electrode is in any direction within an area of a suspended thin film;
preferably, a width of the interdigital electrode is 0.1 μm-20 μm, and preferably 0.5 μm-10 μm; a distance is 2 μm-100 μm; and a thickness is 5 nm-1000 nm, and preferably 10 nm-600 nm;
preferably, an aperture of the interdigital electrode is 5 μm-800 μm, preferably 20 μm-500 μm, and more preferably 70 μm-100 μm, for example, 70 μm, 75 μm, 80 μm, 85 μm, 90 um, or any range between any two values mentioned above or any value within any range;
preferably, a material of the interdigital electrode and a material of the first busbar electrode (5) and the second busbar electrode are any materials having conductive property; and
for example, one or more selected from graphene, topological semimetals, Al, Au, Pt, Cr, W, Mo, Ni, Fe, or Ti.

10. The Lamb wave resonator according to claim 1, further comprising release windows (11) formed in a surface of the piezoelectric layer thin film, wherein the release windows (11) are distributed on a lower side of a first busbar electrode (5), and on an upper side of a second busbar electrode (4); and
for example, a cross section of the release windows (11) is a rectangular and is hollow, four release windows are distributed on the lower side of the first busbar electrode (5), and three release windows are distributed on the upper side of the second busbar electrode (4).
